(19) United States
(12) Patent Application Publication
(10) Pub. No.: US 2026/0096164 A1
(43) Pub. Date: Apr. 2, 2026

(54) STEPPED EPITAXY STRUCTURE FOR STACKED FIELD EFFECT TRANSISTOR (SFET) DEVICE

(71) Applicant: International Business Machines Corporation, Armonk, NY (US)

(72) Inventors: Lijuan Zou, Albany, NY (US); Shay Reboh, Guilderland, NY (US); Chen Zhang, Santa Clara, CA (US); Wai Kin Li, Albany, NY (US)

(21) Appl. No.: 18/901,090

(22) Filed: Sep. 30, 2024

(51) Int. Cl. H01L 29/08; H01L 21/822; H01L 21/8234; H01L 27/06; H01L 27/088; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/017; H10D 84/013; H10D 84/038; H10D 84/83; H10D 88/00; H10D 88/01

(57) ABSTRACT

A stacked field effect transistor structure includes a bottom field effect transistor portion with a lower first drain-source region, a lower second drain-source region, and at least one lower channel region interconnecting the lower first and lower second drain-source regions. At least one of the lower first drain-source region and the lower second drain source region includes a stepped region. The structure also includes an upper field effect transistor portion with an upper first drain-source region, an upper second drain-source region, and at least one upper channel region interconnecting the upper first and upper second drain-source regions. A common gate structure at least partially surrounds the at least one lower channel region and the at least one upper channel region. A contact extends from above the upper field effect transistor portion down to the stepped region.

### BACKGROUND

The present invention relates generally to the electrical, electronic, and computer arts, and, more particularly, to semiconductor devices including stacked field effect transistors (SFETs).

It is a challenge to scale down dual epitaxy formation in stacked FETs using a traditional top blocking spacer/cover layer approach, as the blocking/cover layer deposition may pinch in a narrow trench, e.g., for less than 48 nanometers CPP (ContactPoly Pitch, also called CGP or gate pitch).

In a bottom FET terminal epitaxy-first integration scheme, the epitaxy dimensions/volume are limited to respect a minimum vertical separation distance in between the bottom terminal and the future top FET terminal epitaxy. This impacts the ability of improving a middle-of-line (MOL) via contact to the bottom FET epitaxy as well as posing a risk of direct contact of the MOL via to a channel portion to create shorting.

### BRIEF SUMMARY

Principles of the invention provide techniques for a stepped epitaxy structure for SFET device performance improvement. In one aspect, an exemplary stacked field effect transistor structure includes: a bottom field effect transistor portion including a lower first drain-source region, a lower second drain-source region, and at least one lower channel region interconnecting the lower first and lower second drain-source regions, where at least one of the lower first drain-source region and the lower second drain source region includes a stepped region. Also included are an upper field effect transistor portion including an upper first drain-source region, an upper second drain-source region, and at least one upper channel region interconnecting the upper first and upper second drain-source regions; a common gate structure at least partially surrounding the at least one lower channel region and the at least one upper channel region; and a contact extending from above the upper field effect transistor portion down to the stepped region.

In another aspect, a stacked field effect transistor array includes a plurality of stacked field effect transistor structures as just described; and at least one wiring structure with a plurality of horizontal wires and a plurality of vertical contacts selectively connected to at least a subset of the common gate structures and at least a subset of: the lower first drain-source regions, the lower second drain-source regions, the upper first drain-source regions and the upper second drain-source regions.

In still another aspect, an exemplary method of forming a stacked field effect transistor structure includes providing a field effect transistor initial structure including: a substrate; upper and lower channel stacks separated by insulators, the lower channel stacks being located on the substrate; and dummy gates associated with the upper and lower channel stacks. Further steps include epitaxially growing top drain-source regions between the upper channel stacks; subsequent to epitaxially growing the top drain-source regions, epitaxially growing bottom drain-source regions between the lower channel stacks, where the bottom drain-source regions include stepped regions; replacing the dummy gates with metal gates at least partially surrounding the upper and lower channel stacks; and forming contacts that extend from above the upper channel stacks down to the stepped regions.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
optimizing contact areas with increased epitaxy volume;
enabling stacked FETs to scale down to sub 48 nm CPP;
reduced risk of shorting caused in prior art by MOL contacts being too close to the channel(s); and
the stepped epitaxy makes it easier for a bottom contact trench etch to reach the bottom as now the trench depth is reduced; this also improves the contact area for improved contact.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates stacked FETs where the bottom FET terminal epitaxy includes a stepped structure;

FIG. 2 illustrates a top view of a starting structure for forming the stacked FETs, also generally representative of intermediate steps and a final structure;

FIGS. 3A and 3B illustrate the starting structure with top recessed sacrificial SiGe and nanosheets and bottom recessed sacrificial SiGe and nanosheets after formation of dummy gates, respectively along lines X and Y in FIG. 2 (in subsequent figures, “A” figures are along line X and “B”figures along line Y);

FIGS. 4A and 4B illustrate the starting structure after indenting the sacrificial SiGe layers and formation of inner spacers adjacent to the sacrificial SiGe layers;

FIGS. 5A and 5B illustrate the previous structure after oxide fill, chemical mechanical planarization (CMP), and oxide recess;

FIGS. 6A and 6B illustrate the previous structure after epitaxial growth of the top source-drain regions;

FIGS. 7A and 7B illustrate the previous structure after deposition of conformal nitride liners;

FIGS. 8A and 8B illustrate the previous structure after forming depositing and patterning organic planarization layer(s) (OPL) and etching the nitride liners in areas not protected by the OPL;

FIGS. 9A and 9B illustrate the previous structure after stripping away the OPL and carrying out selective dry etching to etch the oxide;

FIGS. 10A and 10B illustrate the previous structure after bottom epitaxial growth of the bottom source-drain regions;

FIGS. 11A and 11B illustrate the previous structure after backfill with oxide;

FIGS. 12A and 12B illustrate the previous structure after CMP of the oxide;

FIGS. 13A and 13B illustrate the previous structure after SiN cap reactive ion etching (RIE) and oxide RIE;

FIGS. 14A and 14B illustrate the previous structure after pulling the amorphous silicon (a-Si) dummy gates resulting in formation of cavities in the region of the top FET;

FIGS. 15A and 15B illustrate the previous structure after releasing the nanosheets; the SiGe layers are removed from between the Si layers;

FIGS. 16A and 16B illustrate the previous structure after deposition of a high dielectric constant (high-K) liner;

FIGS. 17A and 17B illustrate the previous structure after deposition of work function metals and tungsten, generally designated as gate material;

FIGS. 18A and 18B illustrate the previous structure after carrying out CMP of portions of the gate material and the liner;

FIGS. 19A and 19B illustrate the previous structure after forming MOL contacts during MOL processing and forming BEOL layers during back end of line (BEOL) processing; and

FIG. 20 depicts a stacked field effect transistor array, in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, scaled-down dual epitaxy formation in stacked FETs using a traditional top blocking spacer/cover layer approach is challenging, as the blocking/cover layer deposition may pinch in a narrow trench for, e.g., less than 48 nanometers CPP. Further, in a bottom FET terminal epitaxy-first integration scheme, the epitaxy dimensions/volume are limited to respect a minimum vertical separation distance in between the bottom terminal and the future top FET terminal epitaxy, which can have several drawbacks. Advantageously, one or more embodiments overcome the drawbacks of the prior art by employing stacked FETs where a terminal portion of the bottom FET epitaxy includes a stepped structure to optimize contact area.

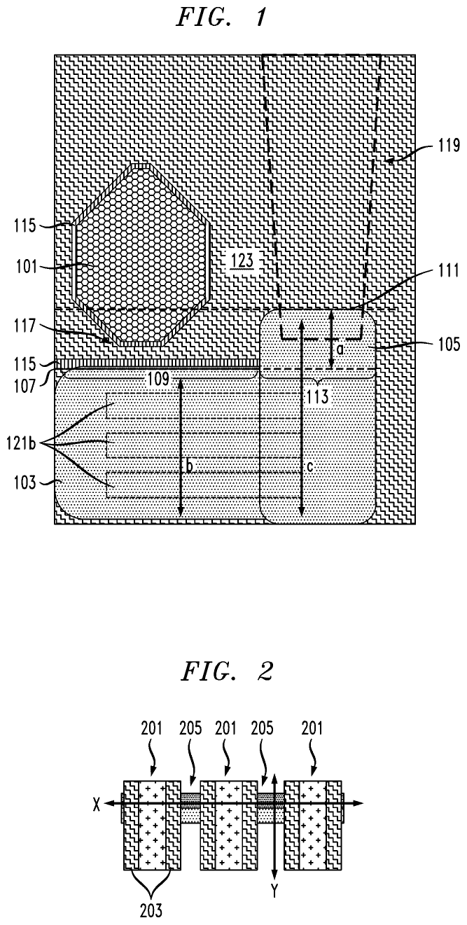

FIG. 1 illustrates stacked FETs where the bottom FET terminal epitaxy, also known as a source/drain epitaxy, includes a stepped structure. The stacked FETs include a top FET with top FET epitaxy 101 that is positioned above a bottom FET with bottom FET epitaxy 103. The bottom FET epitaxy 103 includes a stepped region 105. A top surface 107 of a terminal portion 109 of the bottom FET epitaxy 103 that is under the top FET is at a lower altitude level than a top surface 111 (i.e., top surface of the stepped region 105) of a terminal portion 113 of the bottom FET epitaxy 103 that is not situated under the top FET (stepped region projects up above terminal portion 109 by distance a). That is to say, the terminal portion 113 includes the stepped region 105. The terminal portion 109 of the terminal epitaxy under the top FET channel/gate (distance b) is shorter than the terminal portion 113 of the epitaxy not under the top FET channels/gate (distance c; c=a+b).

At least a part of the terminal portion 109 is covered by a nitride-based liner 115 (e.g., silicon nitride). The top FET epitaxy 101 also includes a nitride-based liner 115. The altitude of the top surface 111 of the terminal portion 113 thus situates at a higher altitude than a bottom surface 117 of the top FET epitaxy 101. A contact 119 can contact the stepped region 105, thereby optimizing contact area. The stepped region 105 also creates distance between the contact 119 and nanosheet channels 121b of the bottom FET to prevent shorting therebetween. Note the interlayer dielectric (ILD) 123. Referring to FIG. 1, a height a of the stepped region ranges from 20 to 60 nanometers; a length of the stepped region (into the page in FIG. 1) ranges from 20 to 40 nanometers; and a width of the stepped region (encompassed by bracket indicating terminal portion 113) ranges from 20 to 40 nanometers. In a non-limiting example, the width of the non-stepped region (encompassed by bracket indicating terminal portion 109) is greater than the width of the stepped region; the length of the stepped region (into the page in FIG. 1) is comparable to the length of the non-stepped region; and dimension b is greater than dimension c.

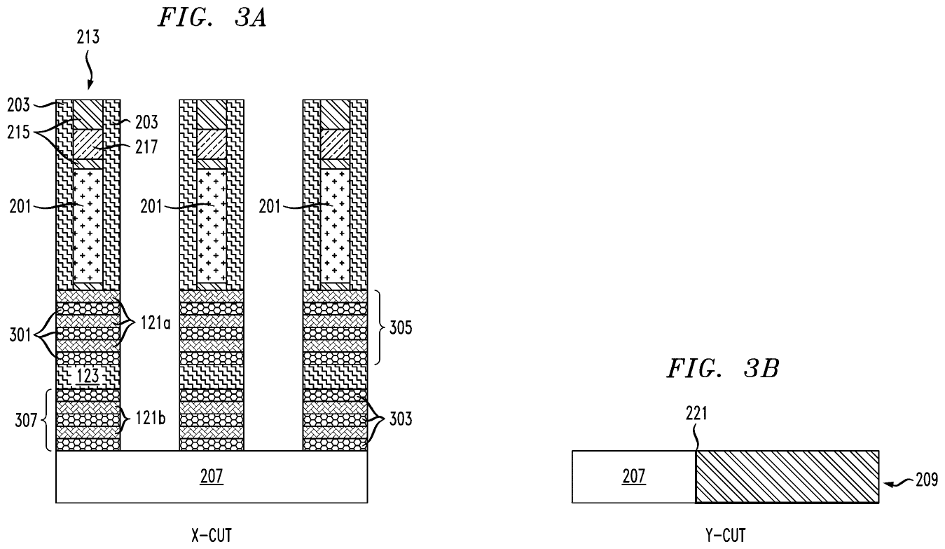

Now consider an exemplary process flow. Refer initially to the top view in FIG. 2 and the views along section lines X and Y in FIG. 2 which are respectively presented in FIG. 3A (along line X) and FIG. 3B (along line Y). In FIGS. 3A-19B, “A” figures are along line X and “B” figures are along line Y. It should be noted that there is no blocking spacer needed for an integration scheme in accordance with one or more embodiments, which scheme is advantageously extendable to sub-48 nm CPP. Components used during fabrication of the stacked FETs may include organic planarization layer(s) (OPL), polycrystalline (PC) semiconductor material (e.g., silicon), silicon boron carbon nitride (SiBCN), oxide, silicon (Si), silicon-germanium (SiGe with various Ge percentages), and silicon nitride (SiN). OPLs can be used to provide planarity and as an etch resistance mask during etching. SiBCN can be used as an insulating layer. The oxide can provide insulating and passivation layers. Amorphous silicon (a-Si) can be used for dummy gates while crystalline silicon can be used for substrate, channel regions, and the like. Too build gates. SiGe can be used as a sacrificial material with layers of Si. SiN can be used as an insulator, passivation layer, chemical barrier, a gate side wall spacer, or for patterning. Note dummy gates 201, outer spacers 203 that can include SiBCN, and regions 205 where epitaxially grown source-drain regions will later be located.

FIGS. 3A and 3B illustrate a starting structure with top recessed sacrificial SiGe 301 and nanosheet channels 121a (top) and bottom recessed sacrificial SiGe 303 and nanosheet channels 121b (bottom) after formation of the dummy gates 201. Additionally, note: the substrate 207 that can include Si; shallow trench isolation (STI) 209; ILD 123; and a hard mask 213 including oxide portions 215 and nitride portion 217. Note an STI liner layer 221 extending between the substrate 207 and STI 209.

Note that a top stack of Si/SiGe layers 305 will be used for formation of a top FET and the bottom stack of Si/SiGe layers 307 will be used for formation of a bottom FET. Conventional techniques can be used to form the starting structure with dummy gates and recessed top and bottom nanosheets.

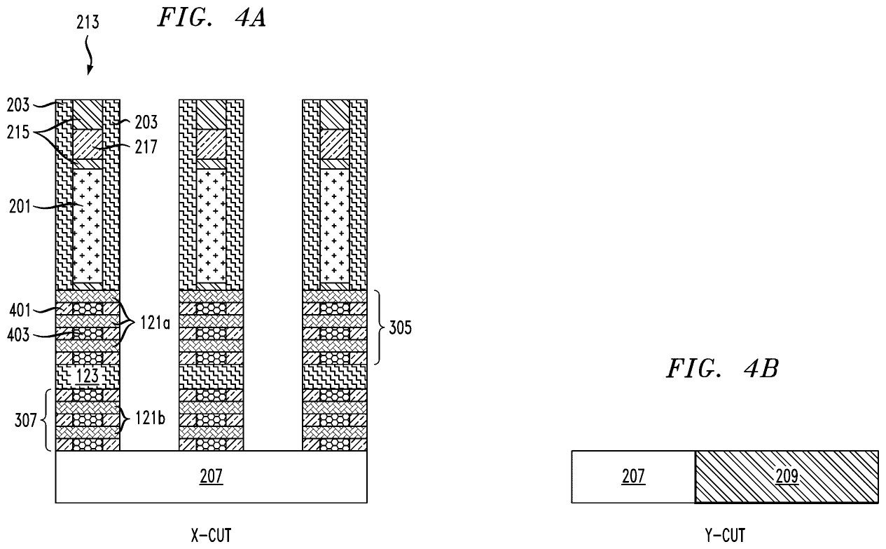

FIGS. 4A and 4B correspond to FIGS. 3A and 3B, after indenting the sacrificial SiGe layers and formation of the inner spacers 401 adjacent to the sacrificial SiGe layers 403. Note outer spacers 203, note the substrate 207, shallow trench isolation (STI) 209, dummy gates 201, ILD 123, a hard mask 213 including oxide portions 215 and nitride portion 217, and nanosheet channels 121a and 121b that can include Si. Conventional techniques can be employed.

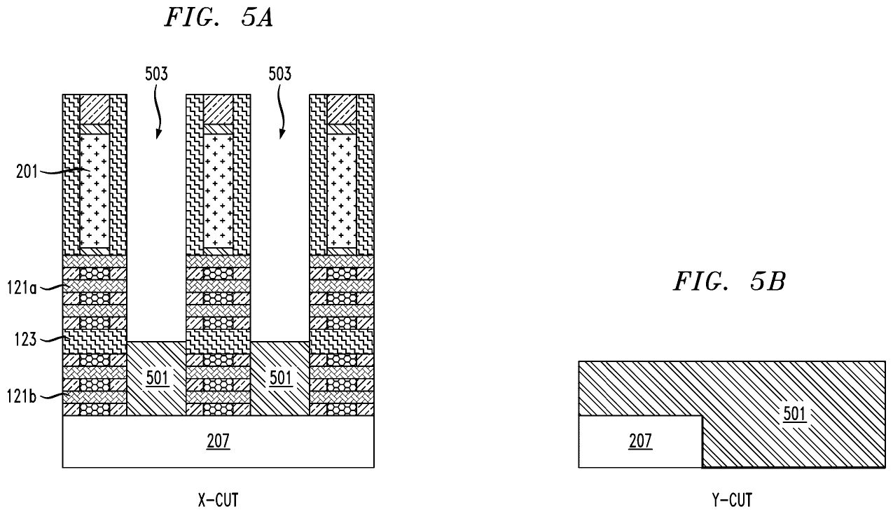

FIGS. 5A and 5B correspond to FIGS. 4A and 4B after oxide fill with oxide 501, chemical mechanical planarization (CMP), and oxide recess. In the example shown, the oxide 501 is disposed in cavities 503 in the region of the bottom FET after recessing. Conventional techniques can be employed.

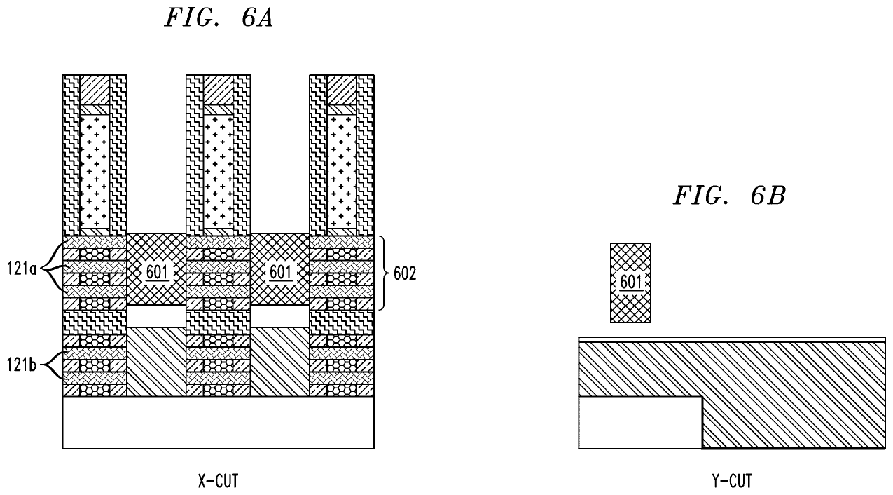

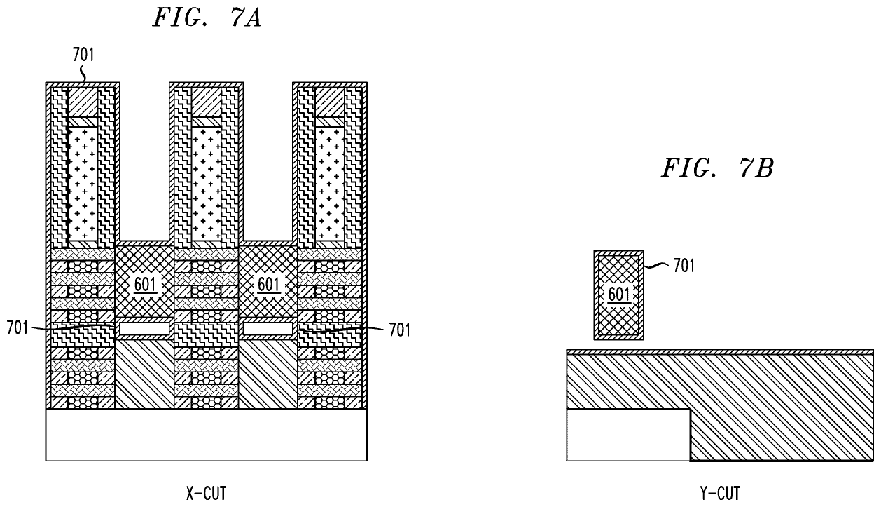

FIGS. 6A and 6B correspond to FIGS. 5A and 5B after epitaxial growth of the top source-drain regions 601 (i.e., for the top FET). The top epitaxy growth occurs in the top FET 602 between upper Si layers (upper nanosheet channels 121a). Conventional techniques can be employed.

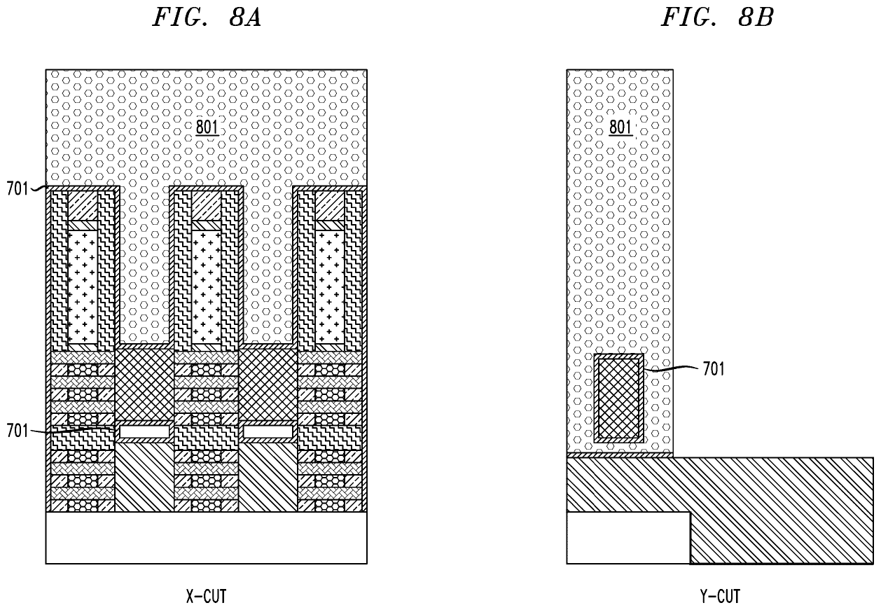

FIGS. 7A and 7B correspond to FIGS. 6A and 6B after deposition of conformal nitride liners 701. The nitride liner 701 can be used as a cap layer and can extend over portions of the top source-drain regions 601.

FIG. 8A and 8B correspond to FIGS. 7A and 7B after forming depositing and patterning OPL 801 and etching the nitride liner 701 in areas not protected by the OPL. Conventional lithography and etching can be employed.

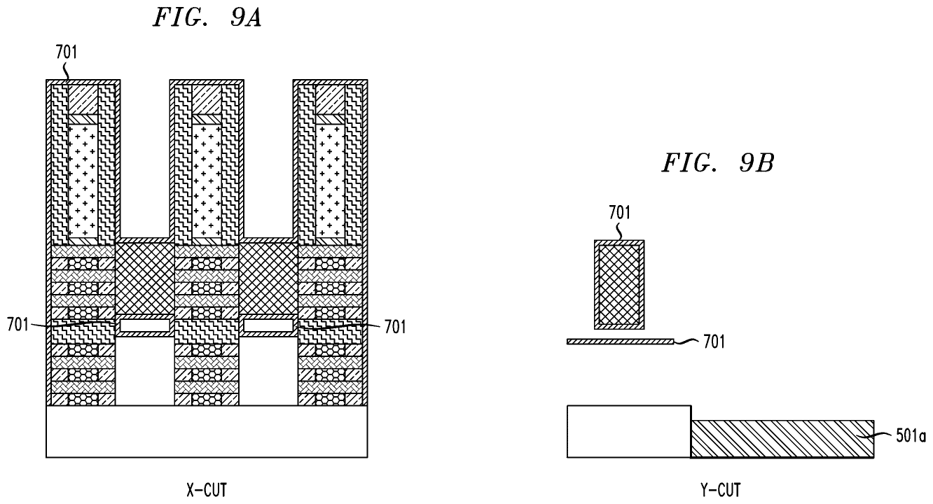

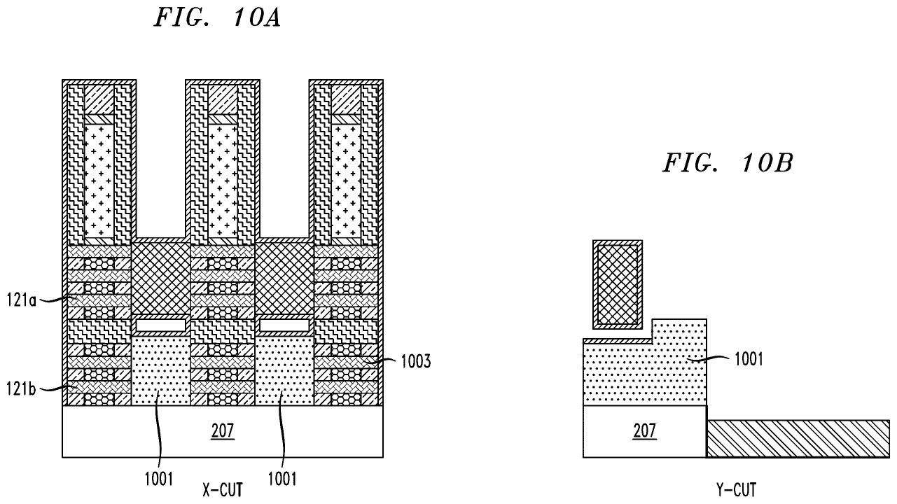

FIGS. 9A and 9B correspond to FIGS. 8A and 8B after stripping away the OPL and carrying out selective dry etching to etch the oxide 501. The remaining oxide after the etching is designated as 501A.

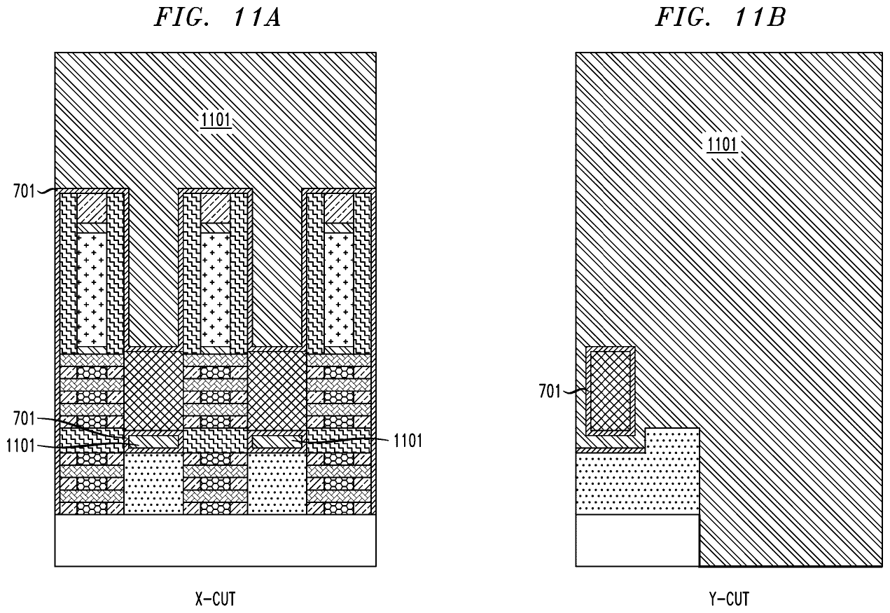

FIGS. 10A and 10B correspond to FIGS. 9A and 9B after bottom epitaxial growth of the bottom source-drain regions 1001. Note upper nanosheet channels 121a and lower nanosheet channels 121b. The bottom epitaxy growth is from the substrate 207 and also from the ends of the Si nanosheets (lower nanosheet channels 121b). Note that a bottom NFET and then a top PFET can be formed, or vice versa.

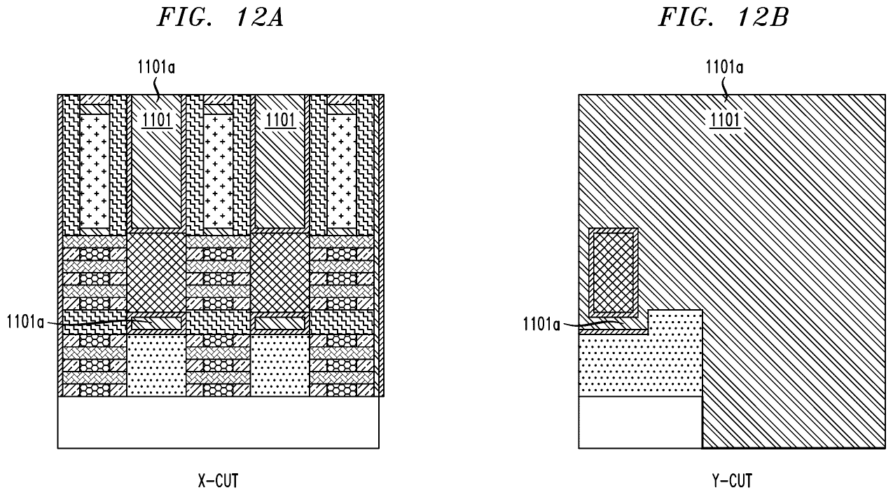

FIGS. 11A and 11B correspond to FIGS. 10A and 10B after backfill with oxide 1101. The oxide 1101 fills space around the liners 701. Conventional techniques can be employed.

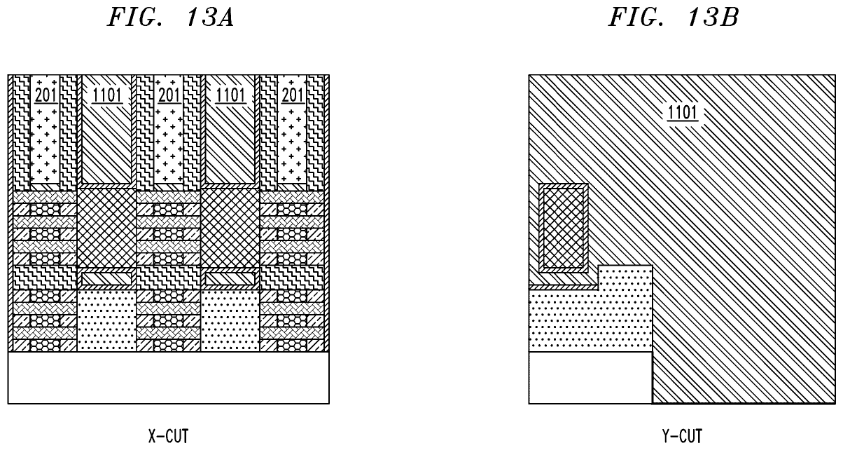

FIGS. 12A and 12B correspond to FIGS. 11A and 11B after CMP of the oxide. Top portions of the oxide 1101 are removed with CMP from the top FET. Remaining oxide after the CMP is designated as 1101a.

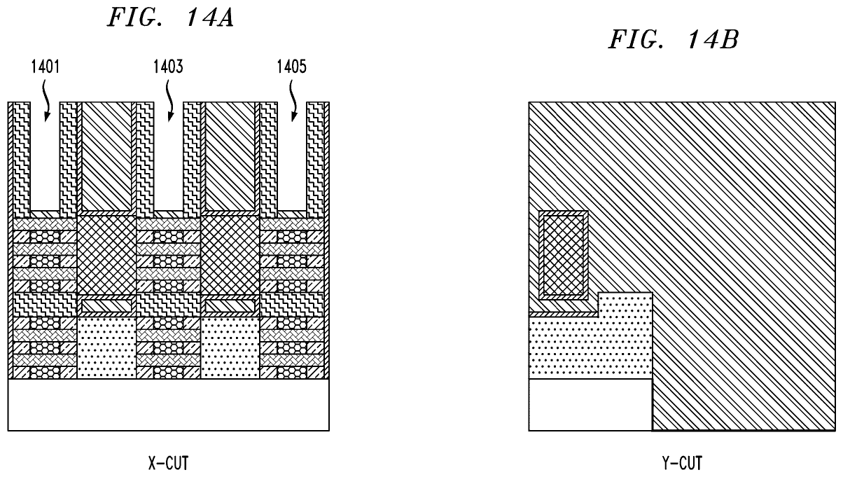

FIGS. 13A and 13B correspond to FIGS. 12A and 12B after SiN cap reactive ion etching (RIE) and oxide RIE. Portions of the remaining oxide 1101A are removed with oxide RIE and the final remaining oxide is designated as 1101B. SiN cap layers are removed with SiN Cap RIE. Note dummy gates 201.

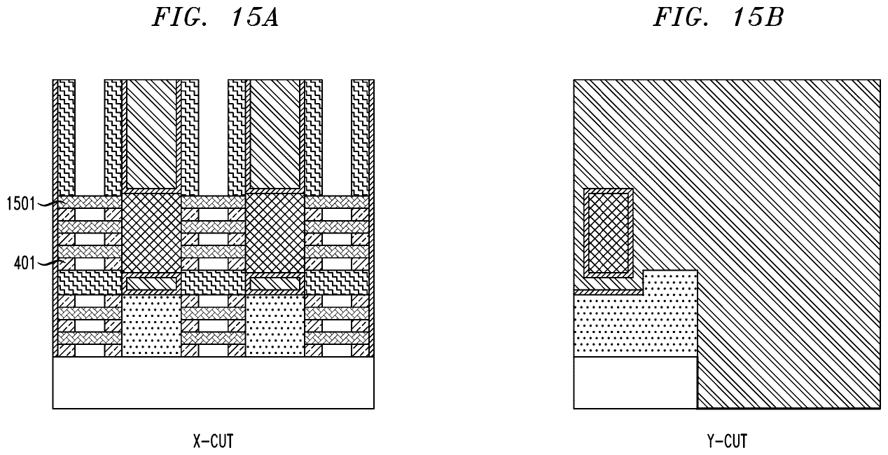

FIGS. 14A and 14B correspond to FIGS. 13A and 13B after pulling the amorphous silicon (a-Si) dummy gates resulting in formation of cavities 1401, 1403, and 1405 in the region of the top FET. Conventional techniques can be employed.

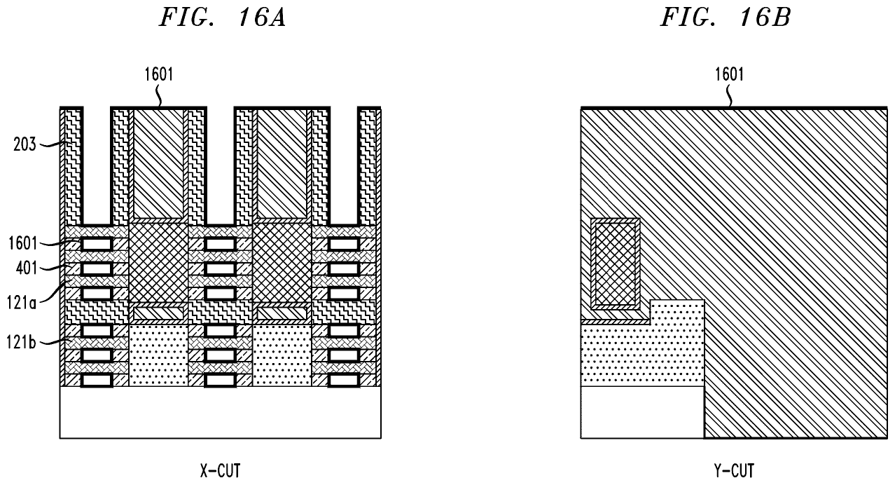

FIGS. 15A and 15B correspond to FIGS. 14A and 14B after releasing the nanosheets; the SiGe layers are removed from between the Si layers 1501 (nanosheet channels). Note inner spacers 401. Conventional techniques can be employed.

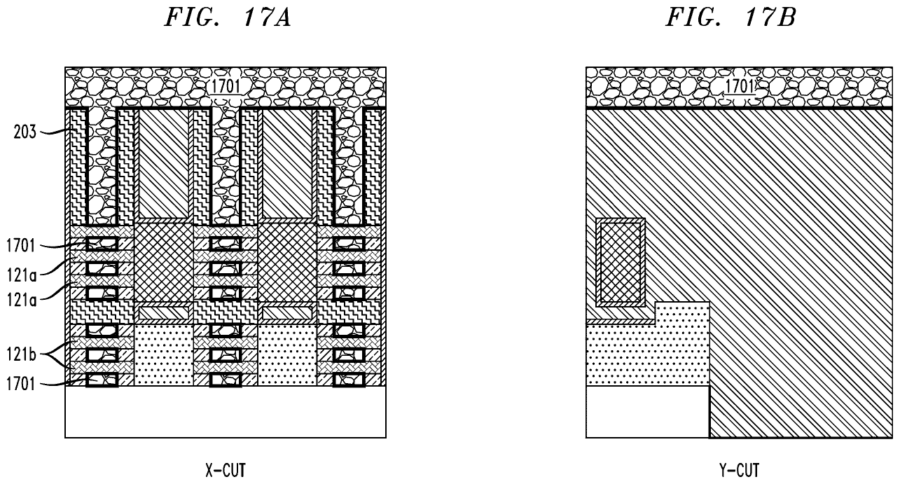

FIGS. 16A and 16B correspond to FIGS. 15A and 15B after deposition of a high dielectric constant (high-K) liner 1601. The liner 1601 covers exposed surfaces of the outer spacers 203, the inner spacers 401, and nanosheet channels 121a and 121b. The skilled artisan will be familiar with gate formation such as high-K metal gates (HKMG) formed using the replacement metal gate process. Such gates include a high-K (e.g., hafnium-based) dielectric and metal portions such as TiN, TiAlN, TiSiN, TaN, TaAlN, TaSiN, Tungsten (W), and the like.

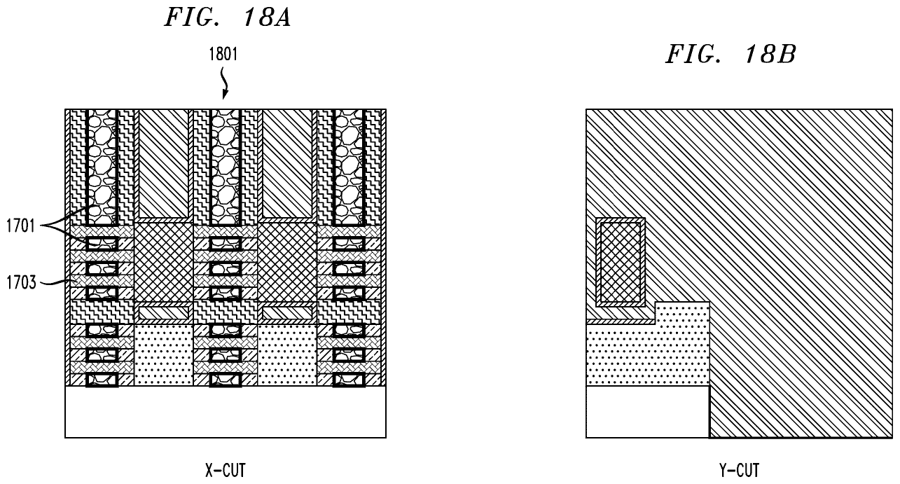

FIGS. 17A and 17B correspond to FIGS. 16A and 16B after deposition of work function metals and tungsten, generally designated as gate material 1701. Note nanosheet channels 121a and 121b. The HKMG surround the channels (gate all around or GAA). Conventional metallization techniques can be employed.

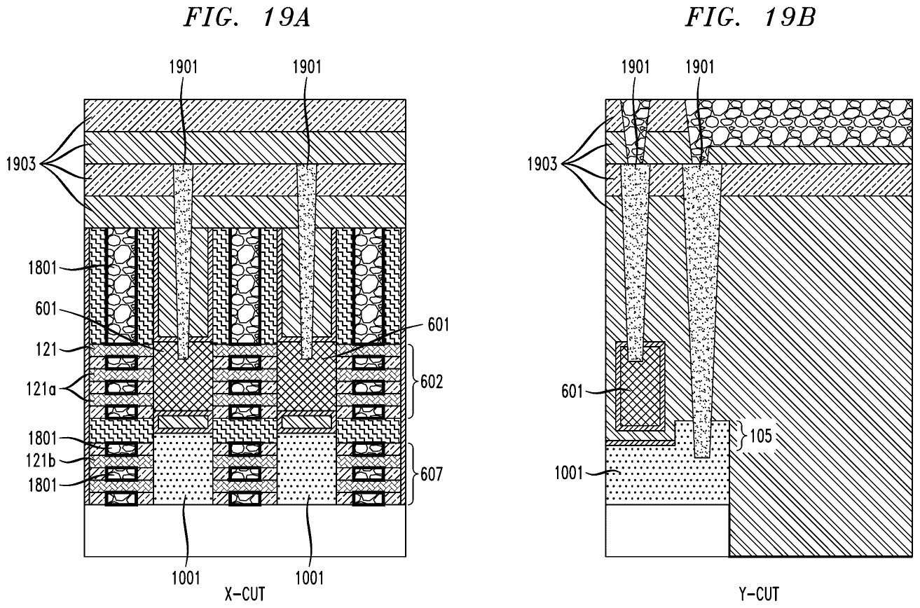

FIGS. 18A and 18B correspond to FIGS. 17A and 17B after carrying out CMP of portions of the gate material 1701 and the liner 1601. Note the high-K metal gates 1801.

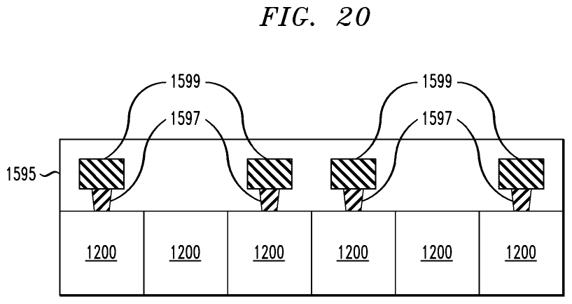

FIGS. 19A and 19B correspond to FIGS. 18A and 18B after forming MOL contacts 1901 during MOL processing and forming BEOL layers 1903 during back end of line (BEOL) processing. Note upper source-drain regions 601 in the top FET 602, and the lower source-drain regions 1001 in the bottom FET 607. The lower source-drain regions 1001 include a stepped region 105 to optimize contact areas for MOL contacts 1901. Note lower nanosheet channels 121b in the bottom FET 607, and upper nanosheet channels 121a in the top FET 602. Gates 1801 at least partially surround the nanosheet channels 121a and 121b. Conventional lithography, etching, and metallization can be employed.

One or more embodiments do not require use of bonding to form the top FET. One or more embodiments can include a tunnel cap layer. One or more embodiments do not require a liner to cover sidewalls of the top FET. One or more embodiments do not require a sacrificial cover layer to protect a top nanosheet channel.

One or more embodiments accordingly provide a stacked transistor structure including a top FET epitaxy and a bottom FET epitaxy with a stepped structure to optimize contact area.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary method of forming a stacked field effect transistor structure, includes providing a field effect transistor initial structure (FIGS. 5A, 5B) including: a substrate 207; upper and lower channel stacks (including nanosheet channels 121a, 121b) separated by insulators (e.g., ILD123), the lower channel stacks being located on the substrate; dummy gates 201 associated with the upper and lower channel stacks; epitaxially growing top drain-source regions between the upper channel stacks (FIGS. 6A, 6B); subsequent to epitaxially growing the top drain-source regions, epitaxially growing bottom drain-source regions between the lower channel stacks (FIGS. 10A,10B), wherein the bottom drain-source regions include stepped regions 105; replacing the dummy gates with metal gates 1801 at least partially surrounding the upper and lower channel stacks (FIGS. 17A, 17B, 18A, 18B); and forming contacts 1901 that extend from above the upper channel stacks down to the stepped regions (FIGS. 19A, 19B).

In some instances, the method further includes not using a blocking spacer during forming of the stacked field effect transistor structure.

In accordance with further aspects of the invention, a stacked field effect transistor structure includes: a bottom field effect transistor portion including a lower first drain-source region 1001, a lower second drain-source region 1001, and at least one lower channel region (e.g., one of the lower nanosheet channels 121b) interconnecting the lower first and lower second drain-source regions, where at least one of the lower first drain-source region and the lower second drain source region includes a stepped region 105; an upper field effect transistor portion including an upper first drain-source region 601, an upper second drain-source region 601, and at least one upper channel region (e.g., one of the upper nanosheet channels 121a) interconnecting the upper first and upper second drain-source regions; a common gate structure (high-K metal gates 1801) at least partially surrounding the at least one lower channel region (e.g., one of the lower nanosheet channels 121b) and the at least one upper channel region; and a contact extending from above the upper field effect transistor portion down to the stepped region.

In some instances of the stacked field effect transistor structure, a top surface 107 of the lower first and lower second drain-source regions under the upper first and upper second drain-source regions is at a lower altitude level than a top surface 111 of the lower first and lower second drain-source regions not situated under the upper first and upper second drain-source regions.

In some instances of the stacked field effect transistor structure, a portion 109 of the lower first and lower second drain-source regions under the upper first and upper second drain-source regions is shorter than a portion 113 of the lower first and lower second drain-source regions that is not under the upper first and upper second drain-source regions.

In some instances of the stacked field effect transistor structure, an altitude of a top surface 111 of the lower first and lower second drain-source regions not situated under the upper first and upper second drain-source regions is at a higher altitude than a bottom surface 117 of the upper first and upper second drain-source regions.

In some instances of the stacked field effect transistor structure, at least a part of the lower first and lower second drain-source regions, other than the stepped region, is covered by a nitride-based liner 115.

In some instances of the stacked field effect transistor structure, a height of the stepped region ranges from 20 to 60 nanometers.

In some instances of the stacked field effect transistor structure, a length of the stepped region ranges from 20 to 40 nanometers.

In some instances of the stacked field effect transistor structure, a width of the stepped region ranges from 20 to 40 nanometers.

In some instances of the stacked field effect transistor structure, a height of the stepped region ranges from 20 to 60 nanometers and a length of the stepped region ranges from 20 to 40 nanometers.

In some instances of the stacked field effect transistor structure, a height of the stepped region ranges from 20 to 60 nanometers; a length of the stepped region ranges from 20 to 40 nanometers; and a width of the stepped region ranges from 20 to 40 nanometers.

In some instances of the stacked field effect transistor structure, a height of the stepped region ranges from 20 to 60 nanometers and a width of the stepped region ranges from 20 to 40 nanometers.

In some instances of the stacked field effect transistor structure, a length of the stepped region ranges from 20 to 40 nanometers, and a width of the stepped region ranges from 20 to 40 nanometers.

In some instances of the stacked field effect transistor structure, a top surface 107 of the drain-source regions of the bottom field effect under the drain-source regions of the top field effect transistor is at a lower altitude level than a top surface 111 of the drain-source regions of the bottom field effect transistor not situated under the drain-source regions of the top field effect transistor 602, and a height of the stepped region ranges from 20 to 60 nanometers.

In some instances of the stacked field effect transistor structure, a portion 109 of the drain-source regions of the bottom field effect transistor under the drain-source regions of the top field effect transistor is shorter than a portion 113 of the bottom field effect transistor that is not under the drain-source regions of the top field effect transistor, and a height of the stepped region ranges from 20 to 60 nanometers.

In some instances of the stacked field effect transistor structure, an altitude of a top surface 111 of the drain-source regions of the bottom field effect transistor 607 not situated under the drain-source regions of the top field effect transistor 602 is at a higher altitude than a bottom surface 117 of the drain-source regions of the top field effect transistor 602, and a height of the stepped region ranges from 20 to 60 nanometers.

In some instances of the stacked field effect transistor structure, a top surface 107 of the drain-source regions of the bottom field effect under the drain-source regions of the top field effect transistor is at a lower altitude level than a top surface 111 of the drain-source regions of the bottom field effect transistor not situated under the drain-source regions of the top field effect transistor 602; a height of the stepped region ranges from 20 to 60 nanometers; a length of the stepped region ranges from 20 to 40 nanometers; and a width of the stepped region ranges from 20 to 40 nanometers.

In some instances of the stacked field effect transistor structure, a portion 109 of the drain-source regions of the bottom field effect transistor under the drain-source regions of the top field effect transistor is shorter than a portion 113 of the bottom field effect transistor that is not under the drain-source regions of the top field effect transistor; a height of the stepped region ranges from 20 to 60 nanometers; a length of the stepped region ranges from 20 to 40 nanometers; and a width of the stepped region ranges from 20 to 40 nanometers.

In some instances of the stacked field effect transistor structure, an altitude of a top surface 111 of the drain-source regions of the bottom field effect transistor 607 not situated under the drain-source regions of the top field effect transistor 602 is at a higher altitude than a bottom surface 117 of the drain-source regions of the top field effect transistor 602; a height of the stepped region ranges from 20 to 60 nanometers; a length of the stepped region ranges from 20 to 40 nanometers; and a width of the stepped region ranges from 20 to 40 nanometers.

In another aspect, referring to FIG. 20, a stacked field effect transistor array includes a plurality of stacked field effect transistor structures as just described, numbered as 1200, and at least one wiring structure with a plurality of horizontal wires 1599 and a plurality of vertical contacts 1597 selectively connected to at least a subset of the gate structures and at least a subset of: the lower first drain-source regions, the lower second drain-source regions, the upper first drain-source regions and the upper second drain-source regions. Any desired elements can be in the array-inverters, ring oscillators, static random access memory (SRAM) and the like-anything with FETs as a fundamental unit. Known materials can be used to form standard interconnects to gate, drain, and source. There can be multiple wiring layers in the wiring structure and the wires and contacts can be in a dielectric 1595.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of exemplary stepped epitaxy structure for SFET device performance improvement as disclosed herein.

An integrated circuit in accordance with aspects of the present inventions can be employed in essentially any application and/or electronic system where one or more aspects of the exemplary stepped epitaxy structure for SFET device performance improvement as disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about”means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A stacked field effect transistor structure comprising:
a bottom field effect transistor portion comprising a lower first drain-source region, a lower second drain-source region, and at least one lower channel region interconnecting the lower first and lower second drain-source regions, wherein at least one of the lower first drain-source region and the lower second drain source region includes a stepped region;
an upper field effect transistor portion comprising an upper first drain-source region, an upper second drain-source region, and at least one upper channel region interconnecting the upper first and upper second drain-source regions;
a common gate structure at least partially surrounding the at least one lower channel region and the at least one upper channel region; and
a contact extending from above the upper field effect transistor portion down to the stepped region.

2. The stacked field effect transistor structure of claim 1, wherein a top surface of the lower first and lower second drain-source regions under the upper first and upper second drain-source regions is at a lower altitude level than a top surface of the lower first and lower second drain-source regions not situated under the upper first and upper second drain-source regions.

3. The stacked field effect transistor structure of claim 1, wherein a portion of the lower first and lower second drain-source regions under the upper first and upper second drain-source regions is shorter than a portion of the lower first and lower second drain-source regions that is not under the upper first and upper second drain-source regions.

4. The stacked field effect transistor structure of claim 1, wherein an altitude of a top surface of the lower first and lower second drain-source regions not situated under the upper first and upper second drain-source regions is at a higher altitude than a bottom surface of the upper first and upper second drain-source regions.

5. The stacked field effect transistor structure of claim 1, wherein at least a part of the lower first and lower second drain-source regions, other than the stepped region, is covered by a nitride-based liner.

6. The stacked field effect transistor structure of claim 1, wherein a height of the stepped region ranges from 20 to 60 nanometers.

7. The stacked field effect transistor structure of claim 1, wherein a length of the stepped region ranges from 20 to 40 nanometers.

8. The stacked field effect transistor structure of claim 1, wherein a width of the stepped region ranges from 20 to 40 nanometers.

9. The stacked field effect transistor structure of claim 1, wherein:
a height of the stepped region ranges from 20 to 60 nanometers;
a length of the stepped region ranges from 20 to 40 nanometers; and
a width of the stepped region ranges from 20 to 40 nanometers.

10. A stacked field effect transistor array comprising:
a plurality of stacked field effect transistor structures comprising:
a bottom field effect transistor portion comprising a lower first drain-source region, a lower second drain-source region, and at least one lower channel region interconnecting the lower first and lower second drain-source regions, wherein at least one of the lower first drain-source region and the lower second drain source region includes a stepped region;
an upper field effect transistor portion comprising an upper first drain-source region, an upper second drain-source region, and at least one upper channel region interconnecting the upper first and upper second drain-source regions;
a common gate structure at least partially surrounding the at least one lower channel region and the at least one upper channel region; and
a contact extending from above the upper field effect transistor portion down to the stepped region; and
at least one wiring structure with a plurality of horizontal wires and a plurality of vertical contacts selectively connected to at least a subset of the common gate structures and at least a subset of:
the lower first drain-source regions, the lower second drain-source regions, the upper first drain-source regions and the upper second drain-source regions.

11. The stacked field effect transistor array of claim 10, wherein a top surface of the lower first and lower second drain-source regions under the upper first and upper second drain-source regions is at a lower altitude level than a top surface of the lower first and lower second drain-source regions not situated under the upper first and upper second drain-source regions.

12. The stacked field effect transistor array of claim 10, wherein a portion of the lower first and lower second drain-source regions under the upper first and upper second drain-source regions is shorter than a portion of the lower first and lower second drain-source regions that is not under the upper first and upper second drain-source regions.

13. The stacked field effect transistor array of claim 10, wherein an altitude of a top surface of the lower first and lower second drain-source regions not situated under the upper first and upper second drain-source regions is at a higher altitude than a bottom surface of the upper first and upper second drain-source regions.

14. The stacked field effect transistor array of claim 10, wherein at least a part of the lower first and lower second drain-source regions, other than the stepped region, is covered by a nitride-based liner.

15. The stacked field effect transistor array of claim 10, wherein a height of the stepped region ranges from 20 to 60 nanometers.

16. The stacked field effect transistor array of claim 10, wherein a length of the stepped region ranges from 20 to 40 nanometers.

17. The stacked field effect transistor array of claim 10, wherein a width of the stepped region ranges from 20 to 40 nanometers.

18. The stacked field effect transistor array of claim 10, wherein:
a height of the stepped region ranges from 20 to 60 nanometers;
a length of the stepped region ranges from 20 to 40 nanometers; and
a width of the stepped region ranges from 20 to 40 nanometers.

19. A method of forming a stacked field effect transistor structure, the method comprising:
providing a field effect transistor initial structure comprising:
a substrate;
upper and lower channel stacks separated by insulators, the lower channel stacks being located on the substrate; and
dummy gates associated with the upper and lower channel stacks;
epitaxially growing top drain-source regions between the upper channel stacks;
subsequent to epitaxially growing the top drain-source regions, epitaxially growing bottom drain-source regions between the lower channel stacks, wherein the bottom drain-source regions include stepped regions;
replacing the dummy gates with metal gates at least partially surrounding the upper and lower channel stacks; and
forming contacts that extend from above the upper channel stacks down to the stepped regions.

20. The method of claim 19, wherein a blocking spacer is not used during forming of the stacked field effect transistor structure.
